(19) United States
(12) Patent Application Publication
(10) Pub. No.: US 2006/0147848 A1
(43) Pub. Date: Jul. 6, 2006

(54) Method of patterning catalyst layer for synthesis of carbon nanotubes and method of fabricating field emission device using the method

(76) Inventors: In-Taek Han, Seoul (KR); Shang-Hyeun Park, Yongin-si (KR); Ha-Jin Kim, Suwon-si (KR)

Correspondence Address: Robert E. Bushnell, Suite 300, 1522 K Street, N.W., Washington, DC, 20005, US

(21) Appl. No.: 11/326,453

(22) Filed: Jan. 6, 2006

(30) Foreign Application Priority Data
Jan. 6, 2005 (KR) 10-2005-0001144

(51) Int. Cl. G03F 7/00

(52) U.S. Cl. 430/327; 430/322

(57) ABSTRACT

A method of patterning a catalyst layer for synthesis of carbon nanotubes (CNTs) and a method of fabricating a field emission device (FED) using the method, whereby a catalyst layer formed of metal salt having a weak-acid negative ion group is formed on a substrate, a photoresist is formed on the catalyst layer, the photoresist is exposed to a light using a photomask with a predetermined pattern, predetermined regions of the photoresist and the catalyst layer are removed by using a strong base developing solution, and the photoresist which remains on the catalyst layer is removed.

### CROSS-REFERENCE TO RELATED PATENT APPLICATIONS AND CLAIM OF PRIORITY

This application claims the benefit of Korean Patent Application No. 10-2005-0001144, filed on Jan. 6, 2005, in the Korean Intellectual Property Office, the disclosure of which is incorporated herein in its entirety by reference.

### BACKGROUND OF THE INVENTION

1. Field of the Invention

The present invention relates to a method of patterning a catalyst layer for synthesis of carbon nanotubes (CNTs) and a method of fabricating a field emission device (FED) using the method.

2. Description of the Related Art

Carbon nanotubes (CNTs) have been used in a variety of elements such as a field emission device (FED), a back-light for a liquid crystal display (LCD), a nanoelectronic device, an actuator, and a battery etc., since unique structural and electrical characteristics of CNTs have been known.

An FED is a display device which emits electrons from an emitter formed on a cathode, and the electrons collide with a phosphor layer formed an anode. In these days, carbon nanotubes (CNTs) having high electron-emitting characteristics have been widely used as an emitter for an FED. An FED using CNTs as an emitter has a low driving voltage, high brightness, and competitive price.

In general, a method of forming carbon nanotubes (CNTS) on a substrate includes screen printing using a carbon nanotube (CNT) paste and carbon nanotube (CNT) growth using chemical vapor deposition (CVD). In CNT growth using CVD, a display apparatus having a high resolution can be fabricated and CNTs can be directly grown on the substrate and thus, a process is simple, and a brisk study of the CNT growth using these advantages has progressed. The CVD includes plasma enhanced CVD (PE CVD) and thermal CVD.

In CNT growth using PE CVD, CNTs can be vertically grown on a substrate, and synthesis can be performed at a lower temperature than in thermal CVD. Vertical growth of CNTs depends on the direction of an electric field applied between an anode and a cathode in a PE CVD system. Thus, the growth direction of CNTs can be adjusted according to the direction of the electric field. In addition, since the growth direction of CNTs is uniform, the density of CNTs can be easily adjusted and electrons can be easily emitted by an electric field.

However, the growth of uniform CNTs cannot be well performed and CNTs that have been grown at a low temperature have comparatively large diameters, and thus, electron-emitting characteristics are not good. In CNT growth using thermal CVD, the growth uniformity of CNTs is very high, and CNTs having a smaller diameter than in PE CVD can be grown such that CNTs having a low turn on voltage can be formed. However, unlike PE CVD, an electric field is not applied to a substrate on which CNTs have been grown, and thus, the growth direction of CNTs is not uniform, gas decomposition is performed by a thermal energy and a growth temperature is high.

In order to grow CNTs using CVD, a catalyst layer patterned on a substrate should be formed. Here, the catalyst layer is used to control the density, diameter, and length of CNT. In order to form a catalyst layer patterned on a substrate, in the prior art, a predetermined catalyst metal is deposited on the substrate in a thin film shape and patterned. However, in the above-mentioned method, deposition costs for forming a thin film of catalyst metal are required and a complex patterning process, that is, exposure, development, etching and stripping processes, should be undergone so that costs increase.

### SUMMARY OF THE INVENTION

The present invention provides a method of patterning a catalyst layer for synthesis of carbon nanotubes (CNTs) by which a process of patterning the catalyst layer can be simplified, and a method of fabricating a field emission device (FED) using the method.

According to an aspect of the present invention, there is provided a method of patterning a catalyst layer, the method including: forming a catalyst layer formed of metal salt having a weak-acid negative ion group on a substrate; forming a photoresist on the catalyst layer; exposing the photoresist to light with the use of a photomask having a predetermined pattern; dissolving and removing a region of the photoresist and a region of the catalyst layer positioned below the region of the photoresist by using a strong base developing solution to form a patterned photoresist and a patterned catalyst layer; and removing the patterned photoresist.

The weak-acid negative ion group of the metal salt may include at least one selected from the group consisting of an acetate group, an oxalate group, and a carbonate group. The metal salt may include at least one selected from the group consisting of Fe, Ni, Co, and Y.

The developing solution may include tetramethylammonium hydroxide (TMAH).

The forming of the catalyst layer may include coating a solution in which the metal salt is dissolved in a solvent and drying the solution. The solvent may include at least one of ethylene glycol and ethanol. The metal salt may have a solubility of 1 mM more than at a room temperature with respect to the solvent. The solution may be coated on the substrate using spin coating or dipping.

The forming of the photoresist may include coating a photoresist solution on the catalyst layer and drying the photoresist solution.

When the photoresist is a positive photoresist, an exposed region of the photoresist and the catalyst layer disposed below the exposed region of the photoresist may be removed using the developing solution.

When the photoresist is a negative photoresist, an unexposed region of the photoresist and the catalyst layer disposed below the unexposed region of the photoresist may be removed using the developing solution.

According to another aspect of the present invention, there is provided a method of fabricating a field emission device, the method including: sequentially stacking a cathode, an insulating layer, and a gate electrode on a substrate and forming an emitter hole through which the cathode is exposed, in the insulating layer; forming a catalyst layer formed of metal salt having a weak-acid negative ion group to cover the gate electrode and the exposed cathode; forming a photoresist to cover the catalyst layer; exposing the photoresist to light in a predetermined pattern; using a strong base developing solution to dissolve and remove a region of the photoresist and a region of the catalyst layer positioned below the region of the photoresist so that a patterned photoresist and a patterened catalyst layer are formed on the exposed cathode; removing the patterned photoresist; and growing carbon nanotubes on the patterned catalyst layer.

The photoresist may be exposed using back-side exposure. In this case, the photoresist may be a negative photoresist, and a predetermined photomask pattern may be formed on the cathode.

The photoresist may be exposed using front-side exposure. In this case, the photoresist may be a positive photoresist.

The carbon nanotubes may be grown using chemical vapor deposition.

### BRIEF DESCRIPTION OF THE DRAWINGS

A more complete appreciation of the present invention, and many of the above and other features and advantages of the present invention, will be readily apparent as the same becomes better understood by reference to the following detailed description when considered in conjunction with the accompanying drawings in which like reference symbols indicate the same or similar components, wherein:

FIGS. 1A through 1E illustrate a method of patterning a catalyst layer for synthesis of carbon nanotubes (CNTs) according to an embodiment of the present invention;

FIGS. 2A through 2C are photos showing CNTs formed on a patterned catalyst layer shown in FIGS. 1A through 1E; and

FIGS. 3A through 3G illustrate a method of fabricating a field emission device (FED) according to another embodiment of the present invention.

### DETAILED DESCRIPTION OF THE INVENTION

Hereinafter, the present invention will be described in detail by explaining exemplary embodiments of the invention with reference to the attached drawings. Like reference numerals in the drawings denote like elements.

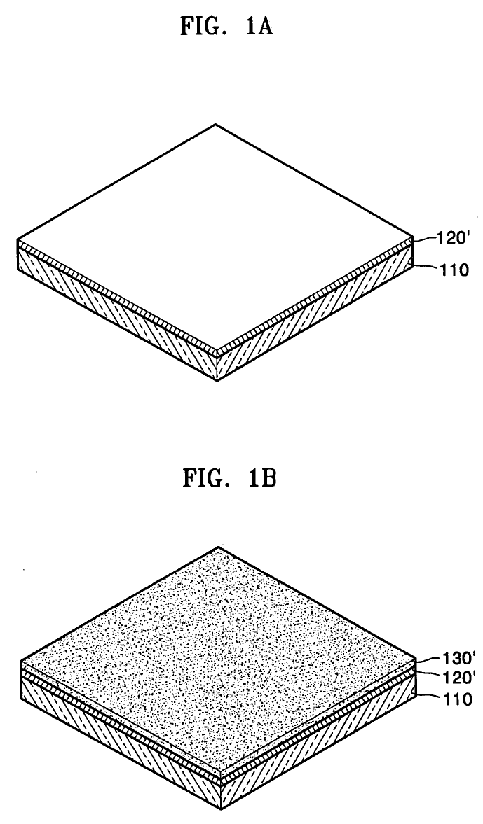

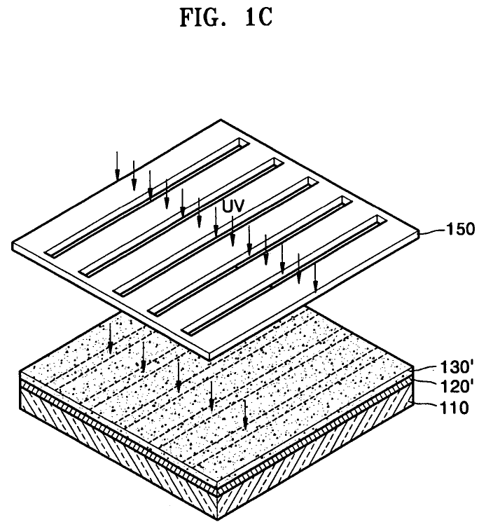

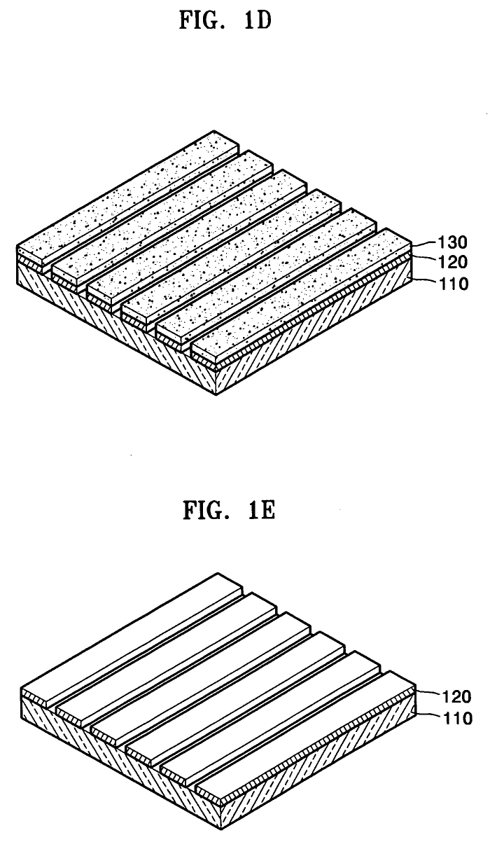

FIGS. 1A through 1E illustrate a method of patterning a catalyst layer for synthesis of carbon nanotubes (CNTs) according to an embodiment of the present invention. Referring to FIG. 1A, a catalyst layer 120′ formed of metal salt is formed on a substrate 110. Specifically, the catalyst layer 120′ is formed by coating a solution in which the metal salt is dissolved in a solvent, on the substrate 110 and drying the solution. Here, the solution may be coated on the substrate 110 using spin coating or dipping.

The metal salt may have a weak-acid negative ion group to be dissolved in a strong base developing solution such as tetramethylammonium hydroxide (TMAH). The weak-acid negative ion group may be at least one of an acetate group, an oxalate group, and a carbonate group. In addition, the metal salt may include at least one of Fe, Ni, Co, and Y. At least one of ethylene glycol and ethanol may be used as the solvent. In this case, the metal salt may have a solubility of at least about 1 mM at room temperature with respect to the solvent. The metal salt is preferably non-dissoluable in acetone, isopropyl alcohol, or a solvent for photoresist strip.

Referring to FIG. 1B, a photoresist 130′ is formed on the catalyst layer 120′. A photoresist solution is coated to cover the upper surface of the catalyst layer 120′ and dried, thereby forming the photoresist 130′. Here, the photoresist 130′ is formed of a material developed by a strong base developing solution. The photoresist 130′ may be a positive photoresist or a negative photoresist.

Referring to FIG. 1C, the photoresist 130′ is exposed to a desired pattern using an UV exposure process using a photomask 150.

Referring to FIG. 1D, predetermined regions of the photoresist 130′ and regions of the catalyst layer 120′ disposed below the predetermined regions of the photoresist 130′ are removed, thereby forming a photoresist 130 and a catalyst layer 120, which are patterned on the substrate 110. FIG. 1D shows the case where the photoresist 130′ is a positive photoresist. In this case, an exposed region of the photoresist 130′ and the catalyst layer 120′ disposed below the exposed region of the photoresist 130′ are removed by a development process. When the photoresist 130′ is a negative photoresist, an unexposed region of the photoresist 130′ and the catalyst layer 120′ disposed below the unexposed region of the photoresist 130 are removed by the development process.

In order to develop the photoresist 130′ and the catalyst layer 120′ using the above-described development process, a strong base developing solution such as TMAH may be used. This is because the strong base developing solution is used to develop the photoresist 130′ and makes a substitution reaction with metal salt having a weak-acid negative ion group of the catalyst layer 120′ disposed below the photoresist 130′ and is used to dissolve the catalyst layer 120′. Specifically, if iron acetate, for example, is used as metal salt of the catalyst layer 120′ and TMAH, for example, is used as the developing solution, the following substitution reaction occurs.
Fe(C₂H₃O₂)₂+2N(CH₃)4OH→Fe(OH)₂+2N(CH₃)₄(C₂H₃O₂)

By the substitution reaction, the catalyst layer 120′ formed of the metal salt having a weak-acid negative ion group can be removed together with the photoresist 130′ using the development process.

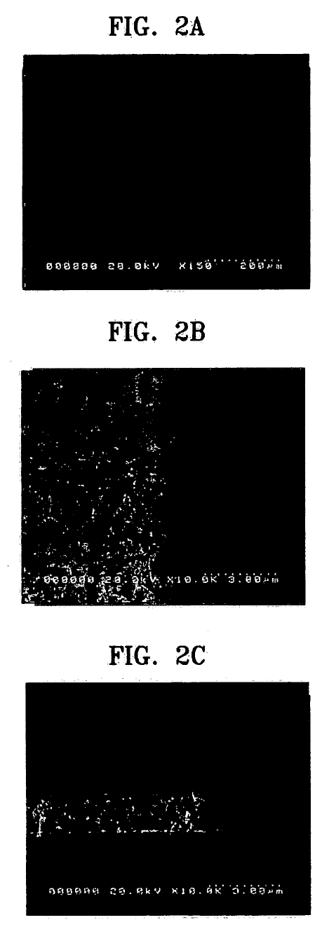

Referring to FIG. 1E, if the photoresist 130 formed on the upper surface of the patterned catalyst layer 120 is removed using a stripper, only the patterned catalyst layer 120 remains on the substrate 110. CNTs can be synthesized on the patterned catalyst layer 120 using CVD. The CNTs that have been grown on the catalyst layer patterned on the substrate in this way are shown in FIGS. 2A through 2C.

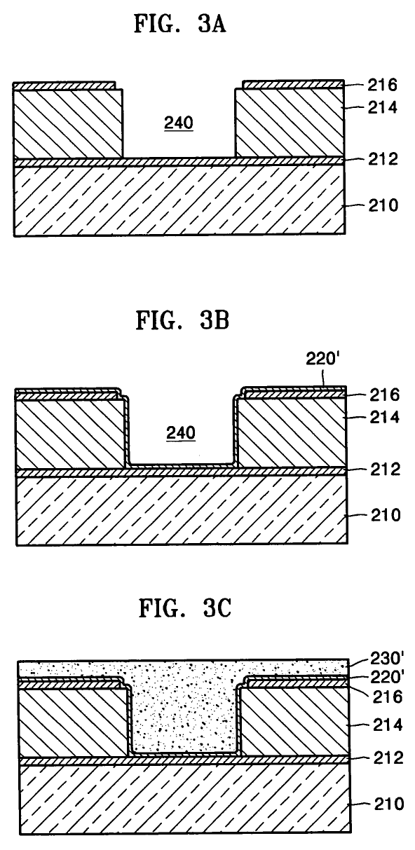

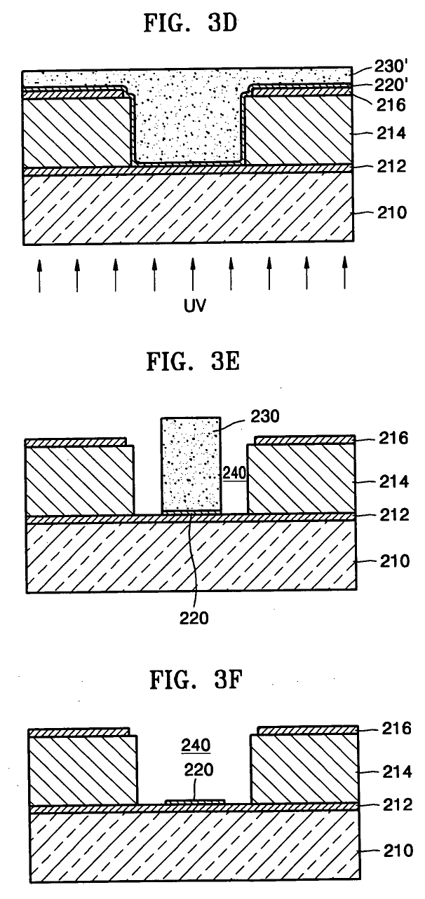

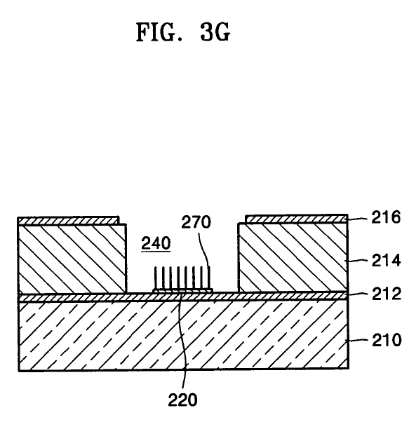

A method of fabricating a field emission device (FED) using the method of patterning a catalyst layer will now be described. FIGS. 3A through 3G illustrate a method of fabricating an FED according to another embodiment of the present invention.

Referring to FIG. 3A, a cathode 212, an insulating layer 214, and a gate electrode 216 are sequentially stacked on a substrate 210 and then, an emitter hole 240 through which the cathode 212 is exposed is formed in the insulating layer 214. Here, a glass substrate may be generally used for the substrate 210. The cathode 212 may be formed of a transparent conductive material such as indium tin oxide (ITO) or the like, and the gate electrode 216 may be formed of a conductive metal such as Cr or the like.

Specifically, a cathode layer formed of a transparent conductive material such as ITO is formed on the substrate 210 to a predetermined thickness, and the cathode layer is patterned in a predetermined shape, for example, in a striped shape so that the cathode 212 is formed. Next, the insulating layer 214 is formed on the entire surface of the cathode 212 to a predetermined thickness. Subsequently, a gate electrode layer is formed on the insulating layer 214. The gate electrode layer is formed by depositing a conductive metal such as Cr to a predetermined thickness using sputtering or the like. The gate electrode layer is patterned in a predetermined shape so that a gate electrode 216 is formed. Next, the insulating layer 214 exposed through the gate electrode 216 is etched so that an emitter hole 240 is formed. In this case, a partial portion of the cathode 212 is exposed through the emitter hole 240.

Referring to FIG. 3B, a catalyst layer 220′ formed of metal salt is formed on the upper surface of a resultant shown in FIG. 3A. Specifically, a solution in which the metal salt is dissolved in a solvent is coated over the upper surface of the resultant shown in FIG. 3A and dried so that the catalyst layer 220′ is formed. Here, the solution may be coated using spin coating or dipping. As described previously, the metal salt may have a weak-acid negative ion group to be dissolved in a strong base developing solution. The weak-acid negative ion group may be at least one of an acetate group, an oxalate group, and a carbonate group. In addition, the metal salt may include at least one of Fe, Ni, Co and Y. At least one of ethylene glycol and ethanol may be used as the solvent. In this case, the metal salt may have a solubility of at least about 1 mM at room temperature with respect to the solvent. The metal salt may not be dissolved in acetone, isopropyl alcohol, or a solvent for photoresist strip.

Referring to FIG. 3C, a photoresist 230′ is formed on the catalyst layer 220′. A photoresist solution is coated to cover the upper surface of the catalyst layer 220′ and dried, thereby forming the photoresist 230′. Here, the photoresist 230′ is formed of a material developed by a strong base developing solution. The photoresist 230′ may be a positive photoresist or a negative photoresist.

Referring to FIG. 3D, the photoresist 230′ is exposed to a desired pattern using an UV exposure process. Here, the photoresist 230′ may be exposed using back-side exposure. When using back-side exposure, the photoresist 230 is a negative photoresist, and a photomask pattern (not shown) for exposing only the photoresist 230′ disposed inside the emitter hole 240 is formed on the cathode 212. The photoresist 230′ may be exposed using front-side exposure. In this case, the photoresist 230′ is a positive photoresist, and a photomask for exposing only the photoresist 230′ disposed outside the emitter hole 240 is provided above the photoresist 230′.

Referring to FIG. 3E, if the photoresist 230′ disposed outside the emitter hole 240 and the catalyst layer 220′ are removed using a development process, the patterned photoresist 230 and the catalyst layer 220 are formed on the cathode 212 inside the emitter hole 240. Here, unexposed regions of the photoresist 230′ and the catalyst layer 220′ are removed using the development process during back-side exposure, and the exposed regions thereof are removed using the development process during front-side exposure. As described above, in order to develop the photoresist 230′ and the catalyst layer 220′ using the above-described development process, a strong base developing solution such as TMAH or the like may be used. This is because the strong base developing solution is used to develop the photoresist 230′ and makes a substitution reaction with metal salt having a weak-acid negative ion group of the catalyst 220′ disposed below the photoresist 230′ and is used to dissolve the catalyst layer 220′.

Referring to FIG. 3F, if the photoresist 230 is removed using a stripper, only the patterned catalyst layer 220 remains on the cathode 212.

Referring to FIG. 3G, carbon nanotubes (CNTs) 270 as an emitter are grown on the patterned catalyst layer 220 so that an FED is fabricated. Here, the CNTs 270 may be grown using CVD. CVD includes PE CVD and thermal CVD.

As described above, in the method of patterning a catalyst layer and the method of fabricating an FED using the method of patterning a catalyst layer according to the present invention, a deposition process of forming a thin film of catalyst metal is not required and the photoresist and the catalyst layer are developed simultaneously such that an additional etching process is not required. As a result, a process of patterning the catalyst layer can be simplified and process costs can be reduced.

While the present invention has been particularly shown and described with reference to exemplary embodiments thereof, it will be understood by those skilled in the art that various changes in form and details may be made therein without departing from the spirit and scope of the invention as defined by the following claims.

What is claimed is:

1. A method of patterning a catalyst layer, the method comprising:
forming a catalyst layer formed of metal salt having a weak-acid negative ion group on a substrate;
forming a photoresist on the catalyst layer;
exposing the photoresist to light with the use of a photomask having a predetermined pattern;
dissolving and removing a region of the photoresist and a region of the catalyst layer positioned below the region of the photoresist by using a strong base developing solution to form a patterned photoresist and a patterned catalyst layer; and
removing the patterned photoresist.

2. The method of claim 1, wherein the weak-acid negative ion group includes at least one selected from the group consisting of an acetate group, an oxalate group, and a carbonate group.

3. The method of claim 1, wherein the metal salt includes at least one selected from the group consisting of Fe, Ni, Co, and Y.

4. The method of claim 1, wherein the developing solution includes tetramethylammonium hydroxide (TMAH).

5. The method of claim 1, wherein the forming of the catalyst layer includes coating a solution in which the metal salt is dissolved in a solvent and drying the solution.

6. The method of claim 5, wherein the solvent includes at least one of ethylene glycol and ethanol.

7. The method of claim 5, wherein the metal salt has a solubility of at least about 1 mM at room temperature with respect to the solvent.

8. The method of claim 5, wherein the solution is coated on the substrate using spin coating or dipping.

9. The method of claim 1, wherein the forming of the photoresist includes coating a photoresist solution on the catalyst layer and drying the photoresist solution.

10. The method of claim 1, wherein the photoresist is a positive photoresist, and the dissolved and removed region of the photoresist is the region exposed to the light.

11. The method of claim 1, wherein the photoresist is a negative photoresist, and the dissolved and removed region of the photoresist is the region unexposed to the light.

12. The method of claim 1, wherein the patterned photoresist is removed using a stripper.

13. The method of claim 12, wherein the metal salt is non-dissoluable in acetone, isopropyl alcohol, and a solvent for photoresist strip.

14. A method of patterning a catalyst layer, the method comprising:
forming a catalyst layer formed of metal salt on a substrate;
forming a photoresist on the catalyst layer;
exposing a region of the photoresist to light in a predetermined pattern;
dissolving and removing a portion of the photoresist and a portion of the catalyst layer positioned below the region of the removed portion of the photoresist by using a base developing solution to form a patterned photoresist and a patterned catalyst layer, the removed portion of the photoresist being one of the region exposed to light and the region unexposed to light, the base developing solution capable of dissolving the portion of the catalyst layer by a substitution reaction with the metal salt; and
removing the patterned photoresist.

15. A method of fabricating a field emission device, the method comprising:
sequentially stacking a cathode, an insulating layer, and a gate electrode on a substrate and forming an emitter hole through which the cathode is exposed, in the insulating layer;
forming a catalyst layer formed of metal salt having a weak-acid negative ion group to cover the gate electrode and the exposed cathode;
forming a photoresist to cover the catalyst layer;
exposing the photoresist to light in a predetermined pattern;
dissolving and removing a region of the photoresist and a region of the catalyst layer positioned below the region of the photoresist so that a patterned photoresist and a patterned catalyst layer are formed on the exposed cathode;
removing the patterned photoresist; and
growing carbon nanotubes on the patterned catalyst layer.

16. The method of claim 15, wherein the weak-acid negative ion group includes at least one selected from the group consisting of an acetate group, an oxalate group, and a carbonate group.

17. The method of claim 15, wherein the metal salt includes at least one selected from the group consisting of Fe, Ni, Co, and Y.

18. The method of claim 15, wherein the developing solution includes tetramethylammonium hydroxide (TMAH).

19. The method of claim 15, wherein the forming of the catalyst layer includes coating a solution in which the metal salt is dissolved in a solvent and drying the solution.

20. The method of claim 19, wherein the solvent includes at least one of ethylene glycol and ethanol.

21. The method of claim 19, wherein the metal salt has a solubility of at least about 1 mM at room temperature with respect to the solvent.

22. The method of claim 19, wherein the solution is coated on the gate electrode and the exposed cathode by using spin coating or dipping.

23. The method of claim 15, wherein the forming of the photoresist includes coating a photoresist solution to cover the catalyst layer and drying the photoresist solution.

24. The method of claim 15, wherein the photoresist is exposed using back-side exposure, and the photoresist is a negative photoresist.

25. The method of claim 15, wherein the photoresist is exposed using front-side exposure, and the photoresist is a positive photoresist.

26. The method of claim 15, wherein the carbon nanotubes are grown using chemical vapor deposition.
